(19) United States
(12) Patent Application Publication
(10) Pub. No.: US 2026/0173696 A1
(43) Pub. Date: Jun. 18, 2026

(54) DISPLAY DEVICE

(71) Applicant: LG Display Co., Ltd., Seoul (KR)

(72) Inventors: HanSaem KANG, Paju-si (KR); Jinhwa SHIN, Paju-si (KR); Bongseok CHOI, Paju-si (KR); DoYoung KWAK, Paju-si (KR); Jongmin JANG, Paju-si (KR); Youngsuk HWANG, Paju-si (KR)

(73) Assignee: LG Display Co., Ltd., Seoul (KR)

(21) Appl. No.: 19/236,650

(22) Filed: Jun. 12, 2025

(30) Foreign Application Priority Data
Dec. 12, 2024 (KR) 10-2024-0184985

(51) Int. Cl. H10K 59/35; H10H 29/30; H10H 29/34; H10H 29/85; H10H 29/851; H10K 59/38

(52) U.S. Cl. CPC H10K 59/353; H10H 29/345; H10H 29/362; H10H 29/851; H10H 29/8517; H10K 59/351; H10K 59/352; H10K 59/38

(57) ABSTRACT

Embodiments of the disclosure may provide a display device capable of repair by including a substrate on which a plurality of subpixels are disposed. The display device includes a first light emitting element that emits no light or emits light of a low grayscale, and a first color conversion layer on the first light emitting element. A second light emitting element and a second color conversion layer disposed thereon and configured to emit light of the same color as the first subpixel. A black matrix is disposed to overlap the first light emitting element and the first color conversion layer, and to cover the first color conversion layer. By reassigning color functionality and selectively masking the defective subpixel, the display device maintains image quality without requiring replacement of the defective element. This approach enables improved visual uniformity and supports pixel repair using modifications to adjacent subpixels.

### CROSS-REFERENCE TO RELATED APPLICATION

This application claims priority benefit from Korean Patent Application No. 10-2024-0184985, filed on Dec. 12, 2024, which is hereby incorporated by reference for all purposes as if fully set forth herein.

### BACKGROUND

### Technical Field

Embodiments of the disclosure relate to an apparatus and particularly to, for example, without limitation, a display device.

### Description of the Related Art

As the information society develops, demand for display devices for displaying images is increasing in various forms. Various display devices, such as liquid crystal display devices and organic light emitting display devices, are being utilized in recent years.

A plurality of pixels may be disposed in the display panel. The plurality of pixels each may include several subpixels.

If some of the subpixels included in one pixel are defective, the pixel may become a defective pixel. In this case, if the subpixels may be repaired, the repair process may be performed on the subpixels.

### BRIEF SUMMARY

The disclosed display device repairs image quality when a subpixel fails, without needing to replace the defective part. Instead, the device adjusts the color conversion layer of a nearby functioning subpixel to take over the intended color role, while a black matrix is applied to cover the non-functioning subpixel and prevent it from being noticeable. To keep the display looking uniform, the grayscale levels of nearby subpixels are adjusted based on their distance from the repaired area.

The device also allows subpixels to change color roles when needed and combines color conversion materials with filters to improve color accuracy. Additionally, the size of each subpixel's light-emitting area can be adjusted to maintain consistent brightness, even when the grayscale level is reduced. These techniques help preserve display quality and reduce power use, particularly in panels that use OLEDs, microLEDs, or quantum dots with color conversion layers.

Example embodiments of the disclosure may provide a display device capable of repairing a pixel through repair of a color conversion layer.

Example embodiments of the disclosure may provide a display device capable of enhancing the image quality of the display panel by pixel repair

Example embodiments of the disclosure may provide a display device capable of reducing the visibility of a defective pixel by pixel repair.

Example embodiments of the disclosure may provide a display device capable of low power consumption by subpixel repair.

Technical benefits of embodiments of the disclosure are not limited to those set forth herein, and other unmentioned benefits would be apparent to one of ordinary skill in the art from the following description.

Embodiments of the disclosure may provide a display device comprising a substrate on which a plurality of pixels including a plurality of subpixels are disposed, wherein each of the plurality of pixels includes a first subpixel including a first light emitting element and a first color conversion layer disposed on the first light emitting element, a second subpixel including a second light emitting element and a second color conversion layer disposed on the second light emitting element, a third subpixel including a third light emitting element and a third color conversion layer disposed on the third light emitting element, and a fourth subpixel including a fourth light emitting element and a fourth color conversion layer disposed on the fourth light emitting element, wherein the first light emitting element, the second light emitting element, and the fourth light emitting element are light emitting elements emitting light of the same color, and wherein an insulation layer is disposed on the first light emitting element, the second light emitting element, the third light emitting element, and the fourth light emitting element, and a black matrix is disposed on the insulation layer.

Embodiments of the disclosure may provide a display device comprising a substrate on which a plurality of pixels including four or more subpixels are disposed, a first light emitting element disposed on the substrate and emitting no light or light of a low grayscale, a first color conversion layer disposed on the first light emitting element, a second light emitting element disposed on the substrate, a second color conversion layer disposed on the second light emitting element, a third light emitting element disposed on the substrate, a third color conversion layer disposed on the third light emitting element, a fourth light emitting element disposed on the substrate, a fourth color conversion layer disposed on the fourth light emitting element, and a black matrix disposed outside the first color conversion layer, the second color conversion layer, the third color conversion layer, and the fourth color conversion layer to overlap the first light emitting element and the first color conversion layer and to cover the first color conversion layer.

According to embodiments of the disclosure, there may be provided a display device capable of repairing a pixel through repair of a color conversion layer.

According to embodiments of the disclosure, there may be provided a display device capable of enhancing the image quality of the display panel by pixel repair

According to embodiments of the disclosure, there may be provided a display device capable of reducing the visibility of a defective pixel by pixel repair.

According to embodiments of the disclosure, there may be provided a display device capable of low power consumption by subpixel repair.

The effects of the disclosure are not limited to the foregoing objects, and other effects will be apparent to one of ordinary skill in the art from the following detailed description.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the following claims. Nothing in this section should be taken as a limitation on those claims. Further aspects and advantages are discussed below in conjunction with embodiments of the disclosure.

It is to be understood that both the foregoing general description and the following detailed description are exemplary and explanatory and are intended to provide further explanation of the inventive concepts as claimed.

### BRIEF DESCRIPTION OF THE SEVERAL VIEWS OF THE DRAWINGS

The disclosure will be more fully understood from the following detailed description and the accompanying drawings, which are provided for illustration only and are not intended to limit the disclosure.

FIG. 1 is a view illustrating a system configuration of a display device according to embodiments of the disclosure;

FIG. 2 is a view illustrating a subpixel according to embodiments of the disclosure;

FIG. 3 is a plan view illustrating a plurality of pixels according to embodiments of the disclosure;

FIG. 4 is a view illustrating repair of a defective subpixel according to embodiments of the disclosure;

FIG. 5 is a cross-sectional view of area A-B of FIG. 4 according to embodiments of the disclosure;

FIG. 6 is a cross-sectional view of area C-D of FIG. 4 according to embodiments of the disclosure;

FIG. 7 is a cross-sectional view of area E-F of FIG. 4 according to embodiments of the disclosure;

FIGS. 8 and 9 are views illustrating a grayscale of a subpixel according to embodiments of the disclosure;

FIG. 10 is a view illustrating a grayscale of a subpixel according to embodiments of the disclosure;

FIG. 11 is a view illustrating an opening area OA of a subpixel SP according to embodiments of the disclosure; and

FIG. 12 is a view illustrating a grayscale of an opening area OA of a subpixel SP according to embodiments of the disclosure.

### DETAILED DESCRIPTION

In the following description of examples or embodiments of the disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the disclosure, detailed descriptions of well-known functions and components incorporated herein will be omitted or may be briefly discussed when it is determined that the description may make the subject matter in some embodiments of the disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments may be provided so that this disclosure may be sufficiently thorough and complete to assist those skilled in the art to fully understand the scope of the present disclosure. Further, the present disclosure is only defined by scopes of claims.

Throughout the drawings and the detailed description, unless otherwise described, the same drawing reference numerals should be understood to refer to the same elements, features, and structures. The relative size and depiction of these elements may be exaggerated for clarity, illustration, and convenience. The progression of processing steps and/or operations described is an example; however, the sequence of steps and/or operations is not limited to that set forth herein and may be changed as is known in the art, with the exception of steps and/or operations necessarily occurring in a particular order. Like reference numerals designate like elements throughout. Names of the respective elements used in the following explanations are selected only for convenience of writing the specification and may be thus different from those used in actual products

A shape, a size, a ratio, an angle, and a number disclosed in the drawings for describing embodiments of the present disclosure may be merely an example. Thus, the present disclosure is not limited to the illustrated details. Like reference numerals refer to like elements throughout. In the following description, when the detailed description of the relevant known function or configuration is determined to unnecessarily obscure an important point of the present disclosure, the detailed description of such known function or configuration may be omitted. When “comprise,” “have,” and “include” described in the present specification are used, another part may be added unless “only” is used. An element described in a singular form is intended to include a plurality of elements, and vice versa, unless the contrary context clearly indicates otherwise.

Any implementation described herein as an “example” is not necessarily to be construed as preferred or advantageous over other implementations.

In the description of the various embodiments of the present disclosure, where positional relationships are described, for example, when a position relation between two parts is described as, for example, “on,” “over,” “under,” and “next,” or the like, one or more other parts may be located between the two parts unless a more limiting term, such as “just” or “direct(ly)” is used. For example, where an element or layer is disposed “on” another element or layer, a third layer or element may be interposed therebetween.

The expression of a first element, a second elements “and/or” a third element should be understood as one of the first, second and third elements or as any or all combinations of the first, second and third elements. By way of example, A, B and/or C can refer to only A; only B; only C; any or some combination of A, B, and C; or all of A, B, and C.

The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, or the third element.

Terms, such as “first”, “second”, “A”, “B”, “(A)”, or “(B)” may be used herein to describe elements of the disclosure. Each of these terms is not used to define essence, order, sequence, or number of elements, etc., but is used merely to distinguish the corresponding element from other elements.

When it is mentioned that a first element “is connected or coupled to”, “contacts or overlaps”, etc., a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc., each other via a fourth element. Here, the second element may be included in at least one of two or more elements that “are connected or coupled to”, “contact or overlap”, etc., each other.

To elaborate, as used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes, etc., are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Rather, these embodiments may be provided so that this disclosure may be sufficiently thorough and complete to assist those skilled in the art to fully understand the scope of the present disclosure. Furthermore, the present disclosure is only defined by scopes of claims.

Features of various embodiments of the present disclosure may be partially or overall coupled to or combined with each other, and may be variously inter-operated with each other and driven technically as those skilled in the art can sufficiently understand. Embodiments of the present disclosure may be carried out independently from each other, or may be carried out together in co-dependent relationship.

Hereinafter, various embodiments of the disclosure are described in detail with reference to the accompanying drawings.

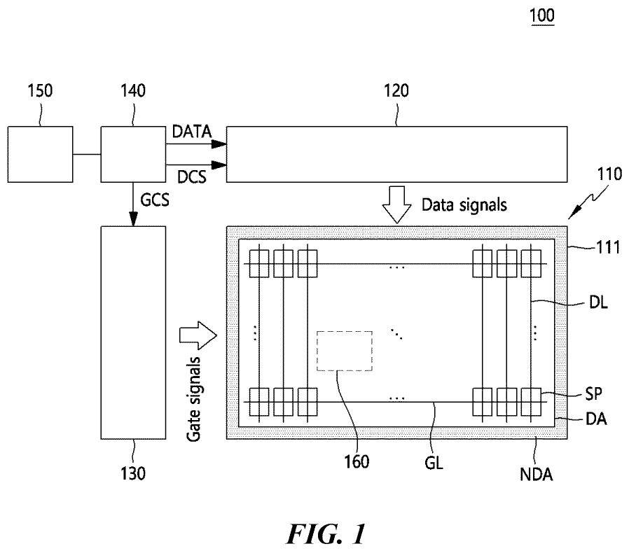

FIG. 1 is a view illustrating a system configuration of a display device 100 according to embodiments of the disclosure.

Referring to FIG. 1, a display device 100 according to embodiments of the disclosure may include a display panel 110 and display driving circuits, as components for displaying images. The display driving circuits are circuits for driving the display panel 110 and may include a data driving circuit 120, a gate driving circuit 130, and a display controller 140.

The display panel 110 may include a substrate 111 and a plurality of subpixels SP disposed on the substrate 111.

The substrate 111 of the display panel 110 may include a display area DA capable of displaying an image and a non-display area NDA positioned outside the display area DA.

A plurality of subpixels SP for image display may be disposed in the display area DA.

In the display panel 110 according to embodiments of the disclosure, the non-display area NDA may be very small. In the disclosure, the non-display area NDA is also referred to as a “bezel.”

Various types of signal lines for driving a plurality of subpixels SP may be disposed on the substrate 111 of the display panel 110.

The display device 100 according to embodiments of the disclosure may be a liquid crystal display device or a self-emission display device in which the display panel 110 emits light by itself. When the display device 100 according to the embodiments of the disclosure is a self-emission display device, each of the plurality of subpixels SP may include a light emitting element.

For example, the display device 100 according to embodiments of the disclosure may be an organic light emitting diode display in which the light emitting element is implemented as an organic light emitting diode (OLED). As another example, the display device 100 according to embodiments of the disclosure may be an inorganic light emitting display device in which the light emitting element is implemented as an inorganic material-based light emitting diode. As another example, the display device 100 according to embodiments of the disclosure may be a quantum dot display device in which the light emitting element is implemented as a quantum dot which is self-emission semiconductor crystal.

The structure of each of the plurality of subpixels SP may vary according to the type of the display device 100. For example, when the display device 100 is a self-emission display device in which the subpixels SP emit light by themselves, each subpixel SP may include a light emitting element that emits light by itself, one or more transistors, and one or more capacitors.

For example, various types of signal lines may include a plurality of data lines DL transferring data signals (also referred to as data voltages or image signals) and a plurality of gate lines GL transferring gate signals (also referred to as scan signals).

The data driving circuit 120 is a circuit for driving the plurality of data lines DL, and may out data signals to the plurality of data lines DL.

The data driving circuit 120 may receive digital image data DATA from the display controller 140 and may convert the received image data DATA into analog data signals and output them to the plurality of data lines DL.

The data driving circuit 120 may be connected to one side (e.g., an upper or lower side) of the display panel 110. In contrast, depending on the driving scheme or the panel design scheme, data driving circuits 120 may be connected with both the sides (e.g., both the upper and lower sides) of the display panel 110, or two or more of the four sides of the display panel 110.

The data driving circuit 120 may be connected outside the display area DA of the display panel 110, but alternatively, the data driving circuit 120 may be disposed in the display area DA of the display panel 110.

The gate driving circuit 130 is a circuit for driving the plurality of gate lines GL, and may output gate signals to the plurality of gate lines GL.

The gate driving circuit 130 may receive a first gate voltage corresponding to a turn-on level voltage and a second gate voltage corresponding to a turn-off level voltage, along with various gate driving control signals GCS, generate gate signals, and supply the generated gate signals to the plurality of gate lines GL.

The display controller 140 is a device for controlling the data driving circuit 120 and the gate driving circuit 130 and may control driving timings for the plurality of data lines DL and driving timings for the plurality of gate lines GL.

The display controller 140 may supply a data driving control signal DCS to the data driving circuit 120 to control the data driving circuit 120 and may supply a gate driving control signal GCS to the gate driving circuit 130 to control the gate driving circuit 130.

The display controller 140 may receive input image data from the host system 150 and supply image data DATA to the data driving circuit 120 based on the input image data.

The display controller 140 may be implemented as a separate component from the data driving circuit 120, or the display controller 140 and the data driving circuit 120 may be integrated into an integrated circuit (IC).

The display controller 140 may be a timing controller used in typical display technology, a control device that may perform other control functions as well as the functions of the timing controller, or a control device other than the timing controller, or may be a circuit in the control device.

The display controller 140 may be mounted on a printed circuit board or a flexible printed circuit and may be electrically connected with the data driving circuit 120 and the gate driving circuit 130 through the printed circuit board or the flexible printed circuit.

To provide a touch sensing function as well as an image display function, the display device 100 according to embodiments of the disclosure may include a touch sensor and a touch sensing circuit that senses the touch sensor to detect whether a touch occurs by a touch object, such as a finger or pen, or the position of the touch.

The touch sensing circuit may include a touch driving circuit that drives and senses the touch sensor and generates and outputs touch sensing data and a touch controller that may detect an occurrence of a touch or the position of the touch using touch sensing data.

The touch sensor may include a plurality of touch electrodes. The touch sensor may further include a plurality of touch lines for electrically connecting the plurality of touch electrodes and the touch driving circuit.

The touch driving circuit may supply a touch driving signal to at least one of the plurality of touch electrodes and may sense at least one of the plurality of touch electrodes to generate touch sensing data.

The touch driving circuit and the touch controller included in the touch sensing circuit may be implemented as separate devices or as a single device. The touch driving circuit and the data driving circuit may be implemented as separate devices or as a single device.

The display device 100 may further include a power supply circuit for supplying various types of power to the display driver integrated circuit and/or the touch sensing circuit.

The display device 100 according to embodiments of the disclosure may further include an electronic device such as a camera (image sensor), a detection sensor, or the like. For example, the detection sensor may be a sensor that detects an object or a human body by receiving light such as infrared rays, ultrasonic waves, or ultraviolet rays.

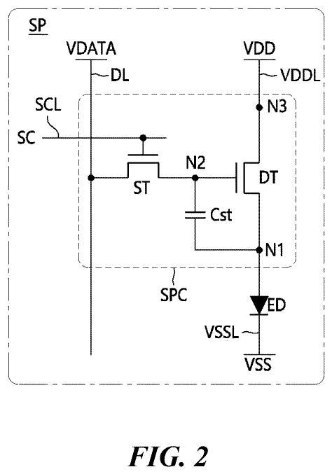

FIG. 2 is a view illustrating a subpixel SP according to embodiments of the disclosure.

Referring to FIG. 2, each of the plurality of subpixels SP may include a light emitting element ED and a subpixel circuit SPC for driving the light emitting element ED.

Referring to FIG. 2, the subpixel circuit SPC may include a plurality of pixel driving transistors and at least one capacitor for driving the light emitting element ED. In the disclosure, the subpixel circuit SPC may drive the light emitting element ED by supplying a driving current to the light emitting element ED at a predetermined timing. The light emitting element ED may be driven by a driving current to emit light.

The plurality of pixel driving transistors may include a driving transistor DT for driving the light emitting element ED and a scan transistor ST that is turned on or off according to the scan signal SC.

The driving transistor DT may supply a driving current to the light emitting element ED.

The scan transistor ST may be configured to control the electrical state of a corresponding node in the subpixel circuit SPC or to control the state or operation of the driving transistor DT.

The at least one capacitor may include a storage capacitor Cst for maintaining a constant voltage during a frame.

To drive the subpixel SP, a data signal VDATA as an image signal and a scan signal SC as a gate signal may be applied to the subpixel SP. Further, for driving the subpixel SP, a common pixel driving voltage including the driving voltage VDD and the base voltage VSS may be applied to the subpixel SP.

The light emitting element ED may be an organic light emitting diode (OLED), an inorganic light emitting diode (LED), or a quantum dot light emitting element. For example, when the light emitting element ED is an organic light emitting diode (OLED), the light emitting element intermediate layer EL of the light emitting element ED may include a light emitting element intermediate layer EL including an organic material.

The driving transistor DT may be a driving transistor for supplying a driving current to the light emitting element ED. The driving transistor DT may be connected between a driving voltage line VDDL and the light emitting element ED.

The driving transistor DT may include a first node N1 electrically connected to the light emitting element ED, a second node N2 to which the data signal VDATA may be applied, and a third node N3 to which the driving voltage VDD is applied from the driving voltage line DVL.

In the driving transistor DT, the second node N2 may be a gate node, the first node N1 may be a source node or a drain node, and the third node N3 may be a drain node or a source node. Hereinafter, for convenience of description, in the driving transistor DT, the second node N2 may be a gate node, the first node N1 may be a source node, and the third node N3 may be a drain node.

The scan transistor ST included in the subpixel circuit SPC illustrated in FIG. 2 may be a switching transistor for transferring the data signal VDATA, which is an image signal, to the second node N2, which is the gate node of the driving transistor DT.

The scan transistor ST may be controlled to be turned on and off by the scan signal SC, which is a gate signal applied through the scan line SCL, which is a type of the gate line GL, to control electrical connection between the second node N2 of the driving transistor DT and the data line DL. The drain electrode or the source electrode of the scan transistor ST may be electrically connected to the data line DL, the source electrode or the drain electrode of the scan transistor ST may be electrically connected to the second node N2 of the driving transistor DT, and the gate electrode of the scan transistor ST may be electrically connected to the scan line SCL.

The storage capacitor Cst may be electrically connected between the first node N1 and the first node N2 of the driving transistor DT. The storage capacitor Cst may include a first capacitor electrode electrically connected to the first node N1 of the driving transistor DT or corresponding to the first node N1 of the driving transistor DT, and a second capacitor electrode electrically connected to the second node N2 of the driving transistor DT or corresponding to the second node N2 of the driving transistor DT.

The capacitor Cst may be an external capacitor intentionally designed to be outside the driving transistor DT, but not a parasite capacitor (e.g., Cgs or Cgd) which is an internal capacitor that may be present between the first node N1 and the second node N2 of the driving transistor DT.

Each of the driving transistor DT and the scan transistor ST may be an n-type transistor or a p-type transistor.

The display panel 110 may have a top emission structure or a bottom emission structure.

When the display panel 110 has a top emission structure, at least a portion of the subpixel circuit SPC may overlap at least a portion of the light emitting element ED in a vertical direction. In contrast, when the display panel 110 has a bottom emission structure, the subpixel circuit SPC may not overlap the light emitting element ED in the vertical direction.

As illustrated in FIG. 2, the subpixel circuit SPC may have a 2T (Transistor) 1C (Capacitor) structure including two transistors DT and ST and one capacitor Cst. In some cases, the subpixel circuit SPC may further include one or more transistors or may further include one or more capacitors.

For example, the subpixel circuit SPC may have an 8T1C structure including 8transistors and 1 capacitor. As another example, the subpixel circuit SPC may have a 6T2C structure including 6 transistors and 2 capacitors. As another example, the subpixel circuit SPC may have a 7T1C structure including 7 transistors and 1 capacitor.

Depending on the structure of the subpixel circuit SPC, the type and number of gate lines or the gate signals supplied to the subpixel SP may vary.

Further, the type and the number of common pixel driving voltages supplied to the subpixel SP may vary according to the structure of the subpixel circuit SPC.

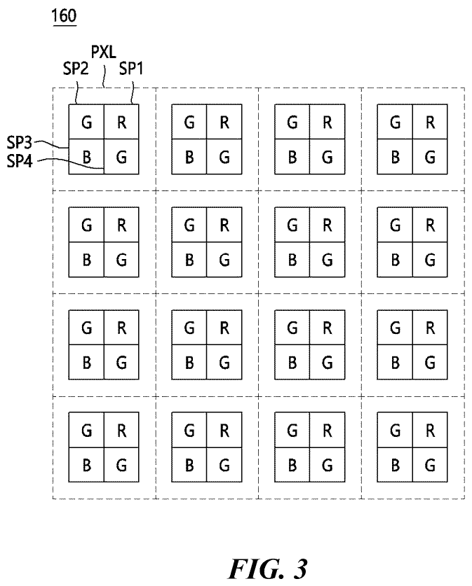

FIG. 3 is a plan view illustrating a plurality of pixels PXL according to embodiments of the disclosure.

Referring to FIG. 3, an enlarged view of the first area 160 of FIG. 1 may be identified.

Referring to FIG. 3, a plurality of pixels PXL may be disposed in the display area DA.

Referring to FIGS. 3, 16 pixels PXL may be identified.

Referring to FIG. 3, the plurality of pixels PXL may be spaced apart from each other by a predetermined distance.

Referring to FIG. 3, each of the plurality of pixels PXL may be disposed in a matrix form.

Referring to FIG. 3, each of the plurality of pixels PXL may include four subpixels SP.

The four subpixels SP may constitute one pixel PXL. By adjusting the grayscale of each of the four subpixels SP, the grayscale and color of one pixel PXL may be controlled.

The four subpixels SP may be disposed at an upper left, an upper right, a lower left, and a lower right end.

The four subpixels SP may be a combination of RGGB, BRRG, RBBG, RGBW, RGBY, WYYW, and RYYW. R is red, G is green, B is blue, W is white, and Y is yellow. M which is a scarlet color and C which is a cyan color may be added to the above-described combination. Hereinafter, for convenience of description, it is assumed that the four subpixels SP are RGGB.

The subpixel SP disposed at the upper right end may be a first subpixel SP1. The first subpixel SP1 may be a subpixel SP representing red.

The subpixel SP disposed at the upper left end may be a second subpixel SP2. The third subpixel SP3 may be a subpixel SP representing green.

The subpixel SP disposed at the lower left end may be a third subpixel SP3. The third subpixel SP3 may be a subpixel SP representing blue.

The subpixel SP disposed at the lower right end may be a fourth subpixel SP4. The fourth subpixel SP4 may be a subpixel SP representing green.

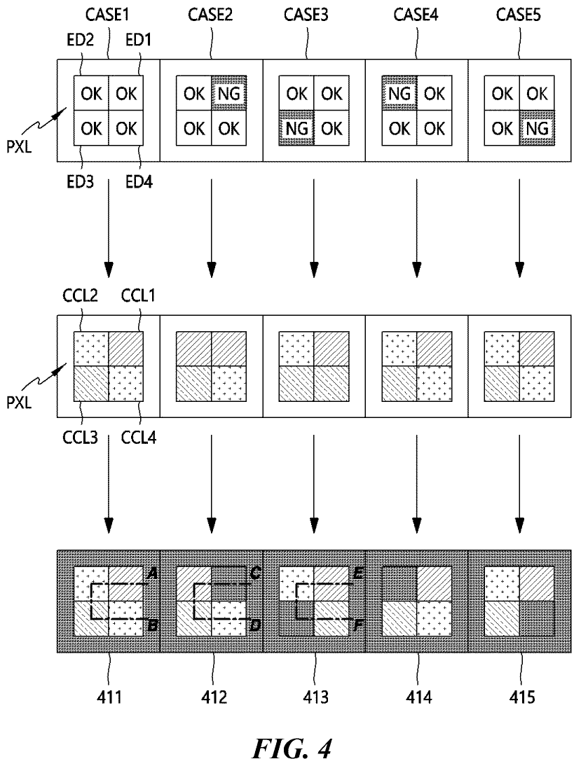

FIG. 4 is a view illustrating repair of a defective subpixel SP according to embodiments of the disclosure.

Referring to FIG. 4, five examples CASE1, . . . CASE5 may be identified.

The first example CASE1 is an example when all of the light emitting elements ED are normal. All of the light emitting elements ED normally emit light, and a color conversion layer may be disposed on the light emitting element ED. A first color conversion layer CCL1 may be disposed on the first light emitting element ED1. A second color conversion layer CCL2 may be disposed on the second light emitting element ED2. A third color conversion layer CCL3 may be disposed on the third light emitting element ED3. A fourth color conversion layer CCL4 may be disposed on the fourth light emitting element ED4. After the color conversion layers are disposed, the black matrix 411 may be disposed around the color conversion layers. The black matrix 411 may be disposed between the color conversion layers.

The second to fifth examples CASE2 to CASE5 are examples when one light emitting element ED is defective or abnormal. In the first example CASE1, the first color conversion layer CCL1 may convert the light of the first light emitting element ED1 into red R, the second color conversion layer CCL2 and the fourth color conversion layer CCL4 may convert the light of the second light emitting element ED2 and the fourth light emitting element ED4 into green G, and the third color conversion layer CCL3 may convert the light of the third light emitting element ED3 into blue B. The second to fifth examples CASE2 to CASE5 illustrate that some of the color conversion layers are changed, which is described below in detail.

The second example CASE2 is an example when one light emitting element ED is abnormal. The first light emitting element ED1 is a defective light emitting element ED that does not emit light. Since the first light emitting element ED1 is defective, there is no light passing through the first color conversion layer CCL1 overlapping the first light emitting element ED1. Therefore, the second color conversion layer CCL2 may be changed in the same manner as the first color conversion layer CCL1. For example, if the first color conversion layer CCL1 was a color conversion layer that converted light into red, the second color conversion layer CCL2 that converts the light of the second light emitting element ED2 into red R may be disposed on the second light emitting element ED2. In other words, the first color conversion layer CCL1 may be a red conversion layer, the second color conversion layer CCL2 may be a red conversion layer, the third color conversion layer CCL3 may be a blue conversion layer, and the fourth color conversion layer CCL4 may be a green conversion layer. Further, when the black matrix 412 is disposed, the first color conversion layer CCL1 may be covered by the black matrix 412. In the second example CASE2, the grayscale and color of light may be implemented through the three subpixels SP.

The third example CASE3 is an example in which one light emitting element ED is abnormal. The third light emitting element ED3 is a defective light emitting element ED that does not emit light. Since the third light emitting element ED3 is defective, there is no light passing through the third color conversion layer CCL3 overlapping the third light emitting element ED3. Therefore, the fourth color conversion layer CCL4 may be changed in the same manner as the third color conversion layer CCL3. For example, the first color conversion layer CCL1 may be a red conversion layer, the second color conversion layer CCL2 may be a green conversion layer, the third color conversion layer CCL3 may be a blue conversion layer, and the fourth color conversion layer CCL4 may be a blue conversion layer. Further, when the black matrix 413 is disposed, the third color conversion layer CCL3 may be covered by the black matrix 413. In the third example CASE3, the grayscale and color of light may be implemented through the three subpixels SP.

The fourth example CASE4 is an example in which one light emitting element ED is abnormal. The second light emitting element ED2 is a defective light emitting element ED that does not emit light. Since the second light emitting element ED2 is defective, there is no light passing through the second color conversion layer CCL2 overlapping the second light emitting element ED2. Therefore, the fourth color conversion layer CCL4 may be changed in the same manner as the second color conversion layer CCL2. For example, the first color conversion layer CCL1 may be a red conversion layer, the second color conversion layer CCL2 may be a green conversion layer, the third color conversion layer CCL3 may be a blue conversion layer, and the fourth color conversion layer CCL4 may be a green conversion layer. Further, when the black matrix 414 is disposed, the second color conversion layer CCL2 may be covered by the black matrix 414. In the fourth example CASE4, the grayscale and color of light may be implemented through the three subpixels SP.

The fifth example CASE5 is an example in which one light emitting element ED is abnormal. The fourth light emitting element ED4 is a defective light emitting element ED that does not emit light. Since the fourth light emitting element ED4 is defective, there is no light passing through the fourth color conversion layer CCL4 overlapping the fourth light emitting element ED4. Therefore, the second color conversion layer CCL2 may be changed in the same manner as the fourth color conversion layer CCL4. For example, the first color conversion layer CCL1 may be a red conversion layer, the second color conversion layer CCL2 may be a green conversion layer, the third color conversion layer CCL3 may be a blue conversion layer, and the fourth color conversion layer CCL4 may be a green conversion layer. Further, when the black matrix 415 is disposed, the fourth color conversion layer CCL4 may be covered by the black matrix 415. In the fifth example CASE5, the grayscale and color of light may be implemented through the three subpixels SP.

In the second to fifth examples CASE2 to CASE5, it has been described that a black matrix is disposed on the defective light emitting element ED. However, a resin material may be applied on the defective light emitting element ED. Further, no other material may be applied on the defective light emitting element ED, and only the defective light emitting element ED may not be driven.

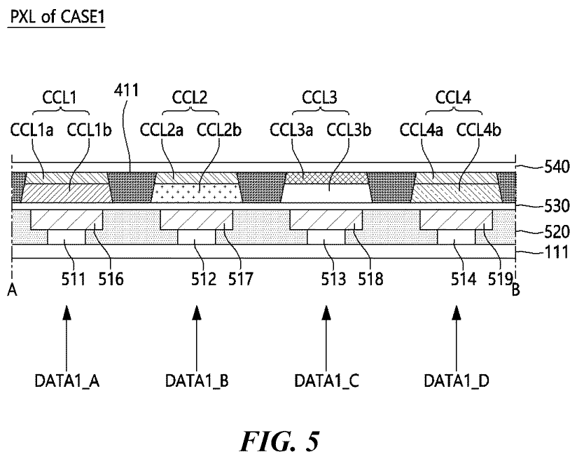

Referring to FIG. 5, area A-B, area C-D, and area E-F may be identified, and hereinafter, a cross-sectional view of each area is described.

FIG. 5 is a cross-sectional view of area A-B of FIG. 4.

Referring to FIG. 5, the substrate 111 may be disposed at the lowermost portion of the display panel 110.

Referring to FIG. 5, subpixel circuits 511, . . . , 514 may be disposed on the substrate 111.

Referring to FIG. 5, the first subpixel circuit 511 may be disposed on the substrate 111, and the first subpixel circuit 511 may include the transistor and the storage capacitor illustrated in FIG. 2. A first light emitting element 516 may be disposed on the first subpixel circuit 511. The first light emitting element 516 may emit white or blue light.

Referring to FIG. 5, the second subpixel circuit 512 may be disposed on the substrate 111, and the second subpixel circuit 512 may include the transistor and the storage capacitor illustrated in FIG. 2. A second light emitting element 517 may be disposed on the second subpixel circuit 512. The second light emitting element 517 may emit white or blue light.

Referring to FIG. 5, the third subpixel circuit 513 may be disposed on the substrate 111, and the third subpixel circuit 513 may include the transistor and the storage capacitor illustrated in FIG. 2. A third light emitting element 518 may be disposed on the third subpixel circuit 513. The third light emitting element 518 may emit white or blue light.

Referring to FIG. 5, the fourth subpixel circuit 514 may be disposed on the substrate 111, and the fourth subpixel circuit 514 may include the transistor and the storage capacitor illustrated in FIG. 2. The fourth light emitting element 519 may be disposed on the fourth subpixel circuit 514. The fourth light emitting element 519 may emit white or blue light.

Referring to FIG. 5, the first insulation layer 520 may be disposed around the subpixel circuits 511, . . . , 514 and the light emitting elements 516, . . . , 519. The first insulation layer 520 may be formed of a plurality of insulating material layers. The first insulation layer 520 may include an inorganic material or an organic material.

Referring to FIG. 5, the second insulation layer 530 may be disposed on the first insulation layer 520. The second insulation layer 530 may include an inorganic material or an insulating material. The second insulation layer 530 may be a layer for planarizing the color conversion layer to be disposed on the second insulation layer 530. In other words, when the second insulation layer 530 is placed flat, the color conversion layers may be placed flat on the second insulation layer 530.

Referring to FIG. 5, the first color conversion layer CCL1 may be disposed on the second insulation layer 530. The first color conversion layer CCL1 may include a first color conversion material layer CCL1a and a first color filter CCL1b. The first color conversion material layer CCL1a may be a layer for converting light into red. The first color conversion material layer CCL1a may be an organic phosphor, an inorganic phosphor, a quantum dot, a color filter, or the like. The first color filter CCL1b may be disposed on the first color conversion material layer CCL1a. The first color filter CCL1b may convert light into red. Since the first color filter CCL1b is disposed on the first color conversion material layer CCL1a, the efficiency of color conversion may be further increased.

Referring to FIG. 5, the second color conversion layer CCL2 may be disposed on the second insulation layer 530. The second color conversion layer CCL2 may include a second color conversion material layer CCL2a and a second color filter CCL2b. The second color conversion material layer CCL2a may be a layer for converting light into green. The second color filter CCL2b may be disposed on the second color conversion material layer CCL2a. The second color filter CCL2b may convert light into green. Since the second color filter CCL2b is disposed on the second color conversion material layer CCL2a, the efficiency of color conversion may be further increased.

Referring to FIG. 5, the third color conversion layer CCL3 may be disposed on the second insulation layer 530. The third color conversion layer CCL3 may include a third color conversion material layer CCL3a and a third color filter CCL3b. The third color conversion material layer CCL3a may be a layer for converting light into blue. However, since the color conversion efficiency for blue is higher than that of red and green, the third color conversion material layer CCL3a may include only transparent materials. The third color filter CCL3b may be disposed on the third color conversion material layer CCL3a. The third color filter CCL3b may convert light into blue. Since the third color filter CCL3b is disposed on the third color conversion material layer CCL3a, the efficiency of color conversion may be further increased.

Referring to FIG. 5, the fourth color conversion layer CCL4 may be disposed on the second insulation layer 530. The fourth color conversion layer CCL4 may include a fourth color conversion material layer CCL4a and a fourth color filter CCL4b. The fourth color conversion material layer CCL4a may be a layer for converting light into green. The fourth color filter CCL4b may be disposed on the fourth color conversion material layer CCL4a. The fourth color filter CCL4b may convert light into green. Since the fourth color filter CCL4b is disposed on the fourth color conversion material layer CCL4a, the efficiency of color conversion may be further increased.

Referring to FIG. 5, a black matrix 411 may be disposed around the color conversion layers CCL1, . . . , CCL4 on the second insulation layer 530. Referring to FIG. 5, the black matrix 411 may be disposed to fill the gaps between the color conversion layers CCL1, . . . , CCL4. In the cross-sectional view illustrated in FIG. 5, the color conversion layers CCL1, . . . , CCL4 are formed before the black matrix 411, so that the color conversion layers CCL1, . . . , CCL4 may have a positive tapered shape, and the black matrix 411 may have an inverted tapered shape.

Referring to FIG. 5, the third insulation layer 540 may be disposed on the color conversion layers CCL1, . . . , CCL4 and the black matrix 411. The third insulation layer 540 may be a layer for protecting the color conversion layers CCL1, . . . , CCL4 from the outside. The third insulation layer 540 may include an inorganic material or an organic material.

The pixel PXL illustrated in FIG. 5 may implement the grayscale and color of light using the first color conversion layer CCL1, the second color conversion layer CCL2, the third color conversion layer CCL3, and the fourth color conversion layer CCL4. The first to fourth light emitting elements 516 to 519 may normally emit light. The first light emitting element 516 may emit light based on the first data DATA1_A, the second light emitting element 517 may emit light based on the second data DATA1_B, the third light emitting element 518 may emit light based on the third data DATA1_C, and the fourth light emitting element 519 may emit light based on the fourth data DATA1_D.

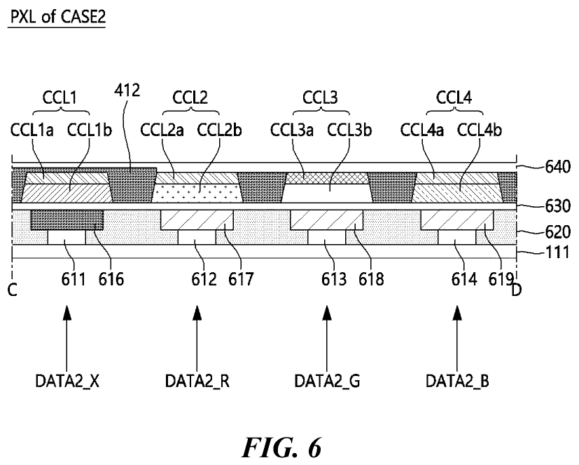

FIG. 6 is a cross-sectional view of area C-D of FIG. 4.

A description of those identical to the features of the components of FIG. 5, among the features of the substrate 111, the subpixel circuits 611, . . . , 614, the light emitting elements 616, . . . , 619, the first insulation layer 520, the second insulation layer 530, the third insulation layer 540, and the color conversion layers of FIG. 6, may be skipped.

Referring to FIG. 6, the first light emitting element 616 may be disposed on the first subpixel circuit 611. The first light emitting element 616 may be a light emitting element ED that may not emit light. In other words, the first light emitting element 616 may be a defective or abnormal light emitting element ED.

The first color conversion layer CCL1 may be disposed on the first light emitting element 616. The first color conversion layer CCL1 may include a first color conversion material layer CCL1a and a first color filter CCL1b. Since the first light emitting element 616 may not emit light, there may be no light passing through the first color conversion layer CCL1. Therefore, the first color conversion layer CCL1 may be covered by the black matrix 412. The black matrix 412 does not cover the second color conversion layer CCL2, the third color conversion layer CCL3, and the fourth color conversion layer CCL4, but the black matrix 412 may be disposed to cover the first color conversion layer CCL1.

Referring to FIG. 6, the second color conversion layer CCL2 may convert light into red. Since light passing through the first color conversion layer CCL1 is not present, the second color conversion layer CCL2 may be changed to have the same configuration as the first color conversion layer CCL1. In other words, the first color conversion layer CCL1 and the second color conversion layer CCL2 may convert light into red, the third color conversion layer CCL3 may convert light into blue, and the fourth color conversion layer CCL4 may convert light into green.

The pixel PXL illustrated in FIG. 6 may implement a grayscale and color of light using the second color conversion layer CCL2, the third color conversion layer CCL3, and the fourth color conversion layer CCL4. The second to fourth light emitting elements 617 to 619 may normally emit light, and the first light emitting element 616 may not emit light. The second light emitting element 617 may emit light based on the second data DATA2_R, the third light emitting element 618 may emit light based on the third data DATA2_G, and the fourth light emitting element 619 may emit light based on the fourth data DATA2_B. The first light emitting element 616 may receive a voltage used as the first data DATA2_X, and the first data DATA2_X may be a voltage for representing black. However, since the first light emitting element 616 may not emit light, the data voltage may not be supplied to the first light emitting element 616.

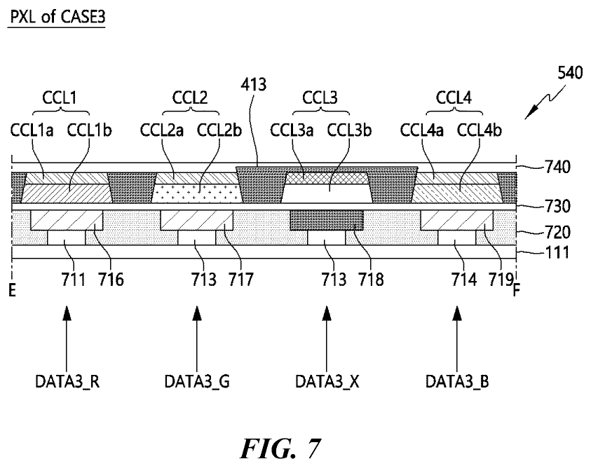

FIG. 7 is a cross-sectional view of area E-F of FIG. 4.

A description of those identical to the features of the components of FIG. 5, among the features of the substrate 111, the subpixel circuits 711, . . . , 714, the light emitting elements 716, . . . , 719, the first insulation layer 720, the second insulation layer 730, the third insulation layer 740, and the color conversion layers of FIG. 7, may be skipped.

Referring to FIG. 7, the third light emitting element 718 may be disposed on the third subpixel circuit 713. The third light emitting element 718 may be a light emitting element ED that may not emit light. In other words, the third light emitting element 718 may be a defective or abnormal light emitting element ED.

A third color conversion layer CCL3 may be disposed on the third light emitting element 718. The third color conversion layer CCL3 may include a third color conversion material layer CCL3a and a third color filter CCL3b. Since the third light emitting element 718 may not emit light, there may be no light passing through the third color conversion layer CCL3. Accordingly, the third color conversion layer CCL3 may be covered by the black matrix 413. The black matrix 413 does not cover the first color conversion layer CCL1, the second color conversion layer CCL2, and the fourth color conversion layer CCL4, but the black matrix 413 may be disposed to cover the third color conversion layer CCL3.

Referring to FIG. 7, the fourth color conversion layer CCL4 may convert light into blue. Since light passing through the third color conversion layer CCL3 is not present, the fourth color conversion layer CCL4 may be changed to have the same configuration as the third color conversion layer CCL3. In other words, the first color conversion layer CCL1 may convert light into red, the second color conversion layer CCL2 may convert light into green, and the third color conversion layer CCL3 and the fourth color conversion layer CCL4 may convert light into blue.

The pixel PXL illustrated in FIG. 7 may implement a grayscale and color of light using the first color conversion layer CCL1, the second color conversion layer CCL2, and the fourth color conversion layer CCL4. The first light emitting element 716, the second light emitting element 717, and the fourth light emitting element 719 may normally emit light, and the third light emitting element 718 may not emit light. The first light emitting element 716 may emit light based on the first data DATA3_R, the second light emitting element 717 may emit light based on the second data DATA3_G, and the fourth light emitting element 719 may emit light based on the fourth data DATA3_B. The third light emitting element 718 may receive a voltage used as the third data DATA3_X, and the third data DATA3_X may be a voltage for representing black. However, since the third light emitting element 718 may not emit light, the data voltage may not be supplied to the third light emitting element 718.

The repair of the pixel PXL including the defective subpixel SP has been described with reference to FIGS. 4 to 7. In other words, one pixel PXL was described. Hereinafter, a method for driving the subpixel SP around the repaired pixel PXL is described.

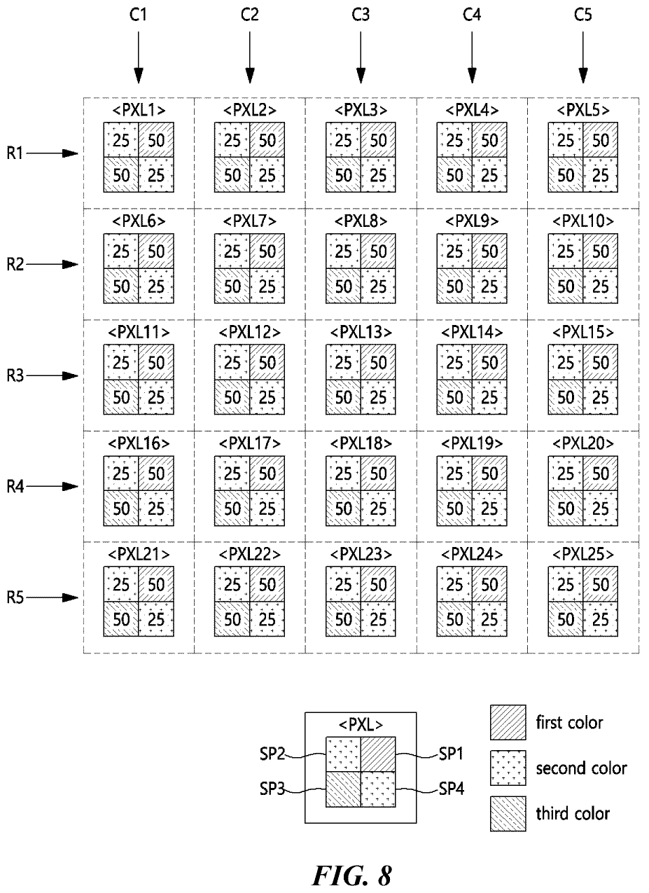

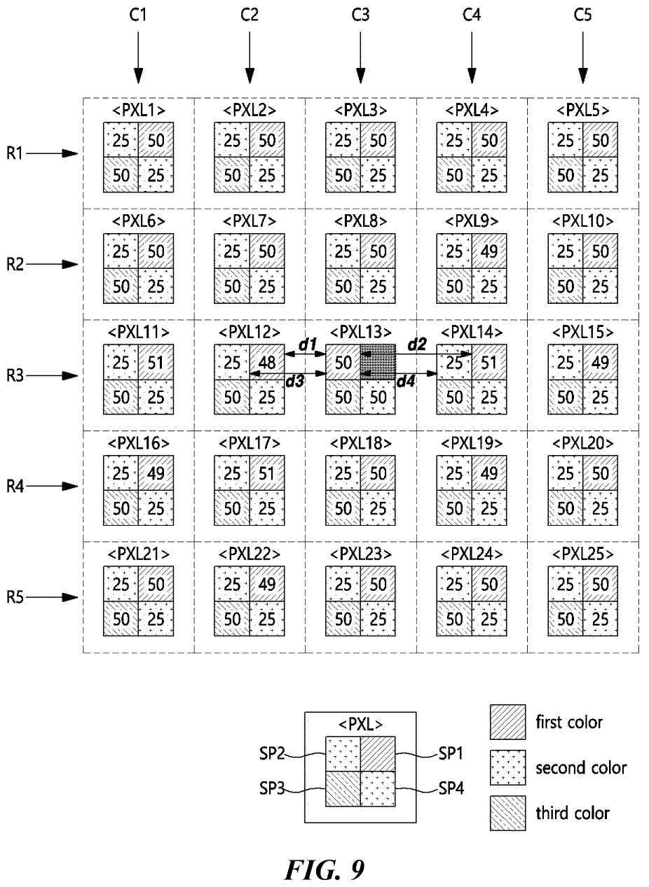

FIGS. 8 and 9 are views illustrating a grayscale of a subpixel SP according to embodiments of the disclosure.

Referring to FIG. 8, a plurality of pixels PXL may be disposed in a matrix form.

The first to fifth pixels PXL1 to PXL5 may be disposed in a first row R1. The first to fifth pixels PXL1 to PXL5 may be disposed in a first column C1, a second column C2, a third column C3, a fourth column C4, and a fifth column C5, respectively.

The sixth to tenth pixels PXL6 to PXL10 may be disposed in a second row R2. The first to fifth pixels PXL1 to PXL5 may be disposed in a first column C1, a second column C2, a third column C3, a fourth column C4, and a fifth column C5, respectively.

The eleventh to fifteenth pixels PXL11 to PXL15 may be disposed in a third row R3. The first to fifth pixels PXL1 to PXL5 may be disposed in a first column C1, a second column C2, a third column C3, a fourth column C4, and a fifth column C5, respectively.

The sixteenth to twentieth pixels PXL16 to PXL20 may be disposed in a fourth row R4. The first to fifth pixels PXL1 to PXL5 may be disposed in a first column C1, a second column C2, a third column C3, a fourth column C4, and a fifth column C5, respectively.

The 21st to 25th pixels PXL21 to PXL25 may be disposed in a fifth row R5. The first to fifth pixels PXL1 to PXL5 may be disposed in a first column C1, a second column C2, a third column C3, a fourth column C4, and a fifth column C5, respectively.

Each of the plurality of pixels PXL may include four subpixels SP. The four subpixels SP may include the subpixels SP of the pixel PXL illustrated in FIG. 3. In other words, the four subpixels SP may represent RGGB colors.

For convenience of description, it is assumed that the plurality of pixels PXL represent white or blue.

Referring to FIG. 8, the four subpixels SP may represent RGGB colors. For example, the first subpixel SP1 may represent a red with a 50th grayscale level. The second subpixel SP2 may represent a green with a 25th grayscale level. The third subpixel SP3 may represent a blue with a 50th grayscale level. The fourth subpixel SP4 may represent a green with a 25th grayscale level.

Referring to FIG. 8, the first to 25th pixels PXL1 to PXL25 include only normal subpixels SP. Referring to FIG. 9, the thirteenth pixel PXL13 includes a defective sub pixel SP.

Referring to FIG. 9, the thirteenth pixel PXL13 may include four subpixels SP. The first subpixel SP1 of the thirteenth pixel PXL13 is a defective subpixel SP. Accordingly, a repair process has been performed on the thirteenth pixel PXL13, and the second subpixel SP2 of the thirteenth pixel PXL13 may emit red light. In the thirteenth pixel PXL13, the second subpixel SP2 may represent, e.g., a red with a 50th grayscale level, the third subpixel SP3 may represent a blue with a 50th grayscale level, and the fourth subpixel SP4 may represent a green with a 50th grayscale level. When the opening area of the second subpixel SP2 is increased, the 30th grayscale level of the second subpixel SP2 having a relatively larger opening area may be identical in the brightness state of the represented color to the 50th grayscale level of the second subpixel SP2 having a relatively smaller opening area. The size adjustment of the opening area may be performed by a repair process.

A repair process has been performed on the thirteenth pixel PXL13, and the second subpixel SP2 represents red. On the other hand, in the remaining pixels PXL, the first subpixel SP1 represents red and the second subpixel SP2 represents green. In other words, the arrangement of red, green, and blue included in the thirteenth pixel PXL13 may be different from the other pixels PXL. Accordingly, the thirteenth pixel PXL13 may be visually recognized by the user. To prevent this, the grayscale of the subpixel SP adjacent to the thirteenth pixel PXL13 may be adjusted.

For example, the first subpixel SP1 of the ninth pixel PXL9 may represent a red with a 49th grayscale level. The first subpixel SP1 of the eleventh pixel PXL11 may represent a red with a 51st grayscale level. The first subpixel SP1 of the twelfth pixel PXL12 may represent a red with a 48th grayscale level. The first subpixel SP1 of the fourteenth pixel PXL14 may represent a red with a 51st grayscale level. The first subpixel SP1 of the fifteenth pixel PXL15 may represent a red with a 49th grayscale level. The first subpixel SP1 of the sixteenth pixel PXL16 may represent a red with a 49th grayscale level. The first subpixel SP1 of the 17th pixel PXL17 may represent a red with a 51st grayscale level. The first subpixel SP1 of the nineteenth pixel PX19L may represent a red with a 49th grayscale level. The first subpixel SP1 of the 22nd pixel PXL22 may represent a red with a 49th grayscale level.

A first distance d1 between the second subpixel SP2 of the thirteenth pixel PXL13 and the first subpixel SP1 of the twelfth pixel PXL12 may be shorter than a second distance d2 between the second subpixel SP2 of the thirteenth pixel PXL13 and the first subpixel SP1 of the fourteenth pixel PXL14. Accordingly, the grayscale of the first subpixel SP1 of the twelfth pixel PXL12 may be relatively further lowered, and the grayscale of the first subpixel SP1 of the fourteenth pixel PXL14 may be relatively further increased.

In addition to the control of the twelfth pixel PXL12 and the fourteenth pixel PXL14, the grayscale of pixels PXL adjacent to the thirteenth pixel PXL13 may be controlled. The optimal grayscale value may be set by simulation or the like. The characteristic clearly appearing here is that the grayscale of the first subpixel SP1 of the twelfth pixel PXL12 and the grayscale of the first subpixel SP1 of the fourteenth pixel PXL14 are different.

A third distance d3 between the second subpixel SP2 of the thirteenth pixel PXL13 and the second subpixel SP2 of the twelfth pixel PXL12 may be equal to a fourth distance d4 between the second subpixel SP2 of the thirteenth pixel PXL13 and the second subpixel SP2 of the fourteenth pixel PXL14. The second subpixel SP2 of the thirteenth pixel PXL13 may display red, whereas the second subpixel SP2 of the twelfth pixel PXL12 and the second subpixel SP2 of the fourteenth pixel PXL14 may display green.

The above description may be summarized as follows. The thirteenth pixel PXL13 may include a defective subpixel SP, and a repair process may be performed on the thirteenth pixel PXL13. Due to the repair process for the thirteenth pixel PXL13, the thirteenth pixel PXL13 may be visually recognized by the user. To prevent this, the gray value for pixels PXL adjacent to the thirteenth pixel PXL13 may be controlled.

In the above description, it is assumed that the pixel PXL includes only one subpixel SP which is defective. Hereinafter, an example in which the pixel PXL includes two defective subpixels SP is described.

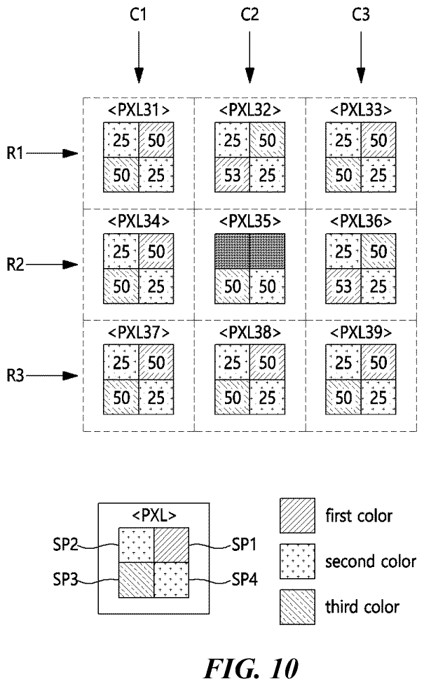

FIG. 10 is a view illustrating a grayscale of a subpixel SP according to embodiments of the disclosure.

Referring to FIG. 10, the first to third pixels PXL31 to PXL33 may be disposed in a first row R1. The first to third pixels PXL31 to PXL33 may be disposed in the first column C1, the second column C2, and the third column C3, respectively.

Referring to FIG. 10, the fourth pixel PXL34 to the sixth pixel PXL36 may be disposed in the first row R1. The fourth to sixth pixels PXL34 to PXL36 may be disposed in the first column C1, the second column C2, and the third column C3, respectively.

Referring to FIG. 10, the seventh pixel PXL37 to the eighth pixel PXL38 may be disposed in the first row R1. The seventh to ninth pixels PXL37 to PXL39 may be disposed in a first column C1, a second column C2, and a third column C3, respectively.

Referring to FIG. 10, the fifth pixel PXL35 may include a defective subpixel SP. In the fifth pixel PXL35, the first subpixel SP1 and the second subpixel SP2 may be defective subpixels SP. Since two of the four subpixels SP are defective, all of the RGB colors may not be implemented with only the remaining two subpixels SP. In this case, the color of the fifth pixel PXL35 may be supplemented by controlling the grayscale of pixels adjacent to the fifth pixel PXL35.

For example, in the fifth pixel PXL35, the first subpixel SP1 and the second subpixel SP2 may be in a black state because they are defective. The third subpixel SP3 may represent a blue with a 50th grayscale level, and the fourth subpixel SP4 may represent a green with a 50th grayscale level.

The second pixel PXL32 may be disposed adjacent to the fifth pixel PXL35. The second pixel PXL32 may include four subpixels SP. In the second pixel PXL32, the first subpixel SP1 may represent a blue with a 50th grayscale level, the second subpixel SP2 and the fourth subpixel SP4 may represent a green with a 25th grayscale level, and the third subpixel SP3 may represent a red with a 53rd grayscale level. Other pixels PXL3 may have an RGBG arrangement of the subpixels SP, while the arrangement of the subpixels SP of the second pixel PXL32 may be BGRG. This is to arrange the subpixel SP representing red among the subpixels SP of the second pixel PXL32 as close to the fifth pixel PXL35 as possible.

The sixth pixel PXL36 may be disposed adjacent to the sixth pixel PXL36. The sixth pixel PXL36 may include four subpixels SP. In the sixth pixel PXL36, the first subpixel SP1 may represent a blue with a 50th grayscale level, the second subpixel SP2 and the fourth subpixel SP4 may represent a green with a 25th grayscale level, and the third subpixel SP3 may represent a red with a 53rd grayscale level. Other pixels PXL3 may have an RGBG arrangement of the subpixels SP, while the arrangement of the subpixels SP of the sixth pixel PXL36 may be BGRG. This is to arrange the subpixel SP representing red among the subpixels SP of the sixth pixel PXL36 as close to the fifth pixel PXL35 as possible.

Referring to the first pixel PXL1 illustrated in FIG. 10, the first subpixel SP1 may represent a red with a 50th grayscale level, the second subpixel SP2 and the fourth subpixel SP4 may represent a green with a 25th grayscale level, and the third subpixel SP3 may represent a blue with a 50th grayscale level. When the opening area of the first subpixel SP1 is increased, the 30th grayscale level of the first subpixel SP1 having a relatively larger opening area may be identical in the brightness state of the represented color to the 50th grayscale level of the first subpixel SP1 having a relatively smaller opening area. The size adjustment of the opening area may be performed by a repair process.

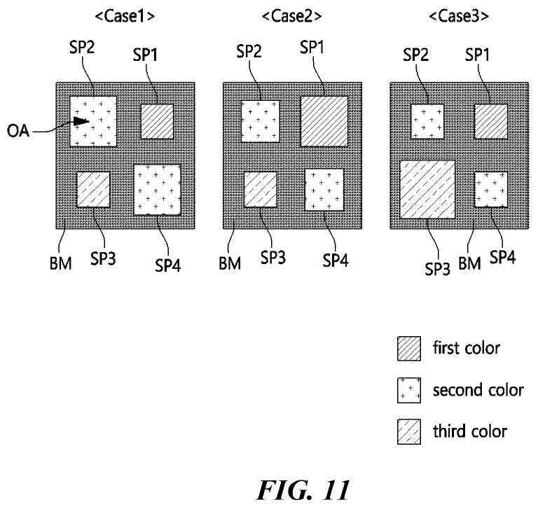

FIG. 11 is a view illustrating an opening area OA of a subpixel SP according to embodiments of the disclosure.

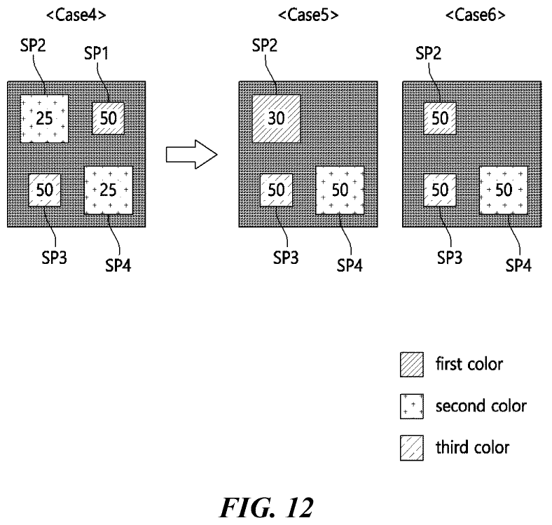

FIG. 12 is a view illustrating a grayscale of an opening area OA of a subpixel SP according to embodiments of the disclosure.

Referring to FIG. 11, the opening areas OA of the plurality of subpixels SP may be designed to be the same as or different from each other. A black matrix BM may be positioned around the plurality of subpixels SP.

Referring to the first example Case 1 of FIG. 11, the opening areas OA of the second subpixel SP2 and the fourth subpixel SP4 may be the largest. The opening area OA of the first subpixel SP1 may be smaller than the opening areas OA of the second subpixel SP2 and the fourth subpixel SP4. The opening area OA of the third subpixel SP3 may be equal to or smaller than the opening area OA of the first subpixel SP1.

Referring to the second example Case 2 of FIG. 11, the opening area OA of the first subpixel SP1 may be the largest. The opening areas OA of the second subpixel SP2 and the fourth subpixel SP4 may be smaller than the opening area OA of the first subpixel SP1. The sizes of the opening areas OA of the second subpixel SP2 and the fourth subpixel SP4 may be the same. The opening area OA of the third subpixel SP3 may be the smallest.

Referring to the third example Case 3 of FIG. 11, the opening area OA of the third subpixel SP3 may be the largest. The opening area OA of the first subpixel SP1 may be smaller than the opening area OA of the third subpixel SP3. The opening areas OA of the second subpixel SP2 and the fourth subpixel SP4 may be equal to or smaller than the opening area OA of the first subpixel SP1. The opening areas OA of the second subpixel SP2 and the fourth subpixel SP4 may be the same.

Referring to the fourth example Case 4 of FIG. 12, the opening areas OA of the first subpixel SP1 and the third subpixel SP3 may be the same. The opening areas OA of the second subpixel SP2 and the fourth subpixel SP4 may be the same. The opening areas OA of the first subpixel SP1 and the third subpixel SP3 may be smaller than the opening areas OA of the second subpixel SP2 and the fourth subpixel SP4. The first subpixel SP1 and the third subpixel SP3 may emit light at a 50th grayscale level, and the second subpixel SP2 and the fourth subpixel SP4 may emit light at a 25 grayscale level.

Referring to the fifth example Case 5 and the sixth example of FIG. 12, the size and grayscale of the opening area OA may be adjusted. Referring to the fifth example Case 5 and the sixth example, the position of the first subpixel SP1 may be covered by the black matrix BM.

Referring to the fourth example Case 4 and the fifth example Case 5, it may be identified that the size of the opening area OA representing the first color is increased. As the opening area OA is increased, the same luminance may be represented even if the grayscale is relatively lowered from the 50th grayscale level to the 30th grayscale level.

Referring to the fourth example Case 4 and the sixth example, the size of the opening area OA with respect to the first color is the same, but only the position representing the first color may vary. In the fourth example Case 4, it may be identified that the first color is represented at a 50th grayscale level through the first subpixel SP1, and in the fifth example Case 5, the first color is represented at a 50th grayscale level through the second subpixel SP2.

The above description may be summarized as follows. The fifth pixel PXL35 may include two defective subpixels SP. For example, the fifth pixel PXL35 may not represent red. In this case, in order to compensate for the red color of the fifth pixel PXL35, the arrangement of the color conversion layers of the second pixel PXL32 and the sixth pixel PXL36 may be changed. Out of the color conversion layers of the second pixel PXL32 and the sixth pixel PXL36, the color conversion layer for red may be disposed as close to the fifth pixel PXL35 as possible. Further, as the grayscale of red represented by the second pixel PXL32 and the sixth pixel PXL36 is increased, the red representation for the fifth pixel PXL35 may be compensated.

A display device according to an embodiment of the disclosure may be described as follows.

Embodiments of the disclosure may provide a display device comprising a substrate on which a plurality of pixels including a plurality of subpixels are disposed, wherein each of the plurality of pixels includes a first subpixel including a first light emitting element and a first color conversion layer disposed on the first light emitting element, a second subpixel including a second light emitting element and a second color conversion layer disposed on the second light emitting element, a third subpixel including a third light emitting element and a third color conversion layer disposed on the third light emitting element, and a fourth subpixel including a fourth light emitting element and a fourth color conversion layer disposed on the fourth light emitting element, wherein the first light emitting element, the second light emitting element, and the fourth light emitting element are light emitting elements emitting light of the same color, and wherein an insulation layer is disposed on the first light emitting element, the second light emitting element, the third light emitting element, and the fourth light emitting element, and a black matrix is disposed on the insulation layer.

Embodiments of the disclosure may provide a display device comprising a substrate on which a plurality of pixels including four or more subpixels are disposed, a first light emitting element disposed on the substrate and emitting no light or light of a low grayscale, a first color conversion layer disposed on the first light emitting element, a second light emitting element disposed on the substrate, a second color conversion layer disposed on the second light emitting element, a third light emitting element disposed on the substrate, a third color conversion layer disposed on the third light emitting element, a fourth light emitting element disposed on the substrate, a fourth color conversion layer disposed on the fourth light emitting element, and a black matrix disposed outside the first color conversion layer, the second color conversion layer, the third color conversion layer, and the fourth color conversion layer to overlap the first light emitting element and the first color conversion layer and to cover the first color conversion layer.

Light passing through the first color conversion layer and the second color conversion layer may be converted into a first color.

Light passing through the third color conversion layer may be converted into a second color, and light passing through the fourth color conversion layer may be converted into a third color. The First color, the second color, and the third color may be different colors.

The first color conversion layer may include a first color conversion material layer and a first color filter, and the second color conversion layer may include a second color conversion material layer and a second color filter.

The first color conversion material layer may include a material included in the second color conversion material layer. A color of light passing through the first color filter may be the same as a color of light passing through the second color filter.

The black matrix may cover the first color filter. The black matrix may not contact an upper surface of the second color filter.

The third color conversion layer may include a third color conversion material layer and a third color filter. The first color conversion material layer may include a material converting a color of light. The third color conversion material layer may include a transparent material.

The display device may further comprise a first subpixel circuit driving the first light emitting element. The first subpixel circuit may not supply a data voltage to the first light emitting element or may supply a voltage for the first light emitting element to represent black.

The display device may further comprise the first subpixel including the first light emitting element and the first color conversion layer, the second subpixel including the second light emitting element and the second color conversion layer, the third subpixel including the third light emitting element and the third color conversion layer, and the fourth subpixel including the fourth light emitting element and the fourth color conversion layer, and a first pixel including the first subpixel, the second subpixel, the third subpixel, and the fourth subpixel.

The display device may further comprise a second pixel including a fifth subpixel and disposed in line with the first pixel and a third pixel including a sixth subpixel and disposed in line with the first pixel and the second pixel. A first distance from the second subpixel to the fifth subpixel may be shorter than a second distance from the second subpixel to the sixth subpixel.

When the first pixel, the second pixel, and the third pixel are controlled to represent the same color, a grayscale of the fifth subpixel of the second pixel may be different from a grayscale of the sixth subpixel of the third pixel.

Each of the second subpixel, the fifth subpixel, and the sixth subpixel may display a different grayscale. The second subpixel, the fifth subpixel, and the sixth subpixel may display the same color.

The second pixel may include a seventh subpixel disposed farther from the second subpixel than the fifth subpixel. The third pixel may include an eighth subpixel disposed closer to the second subpixel than the sixth subpixel. A third distance from the second subpixel to the seventh subpixel may be the same as a fourth distance from the second subpixel to the eighth subpixel.

The second subpixel may display a first color, and the seventh subpixel and the eighth subpixel display a second color different from the first color.

The second light emitting element may not emit light or emit light of a low grayscale. The black matrix may be disposed to overlap the second light emitting element and the second color conversion layer, and to cover the second color conversion layer.

The display device may further comprise a first subpixel including the first light emitting element and the first color conversion layer, a second subpixel including the second light emitting element and the second color conversion layer, a third subpixel including the third light emitting element and the third color conversion layer, and a fourth subpixel including the fourth light emitting element and the fourth color conversion layer, a first pixel including the first subpixel, the second subpixel, the third subpixel, and the fourth subpixel, and a fifth subpixel positioned closer to the second subpixel than the third subpixel. The third subpixel may display a first color, the fourth subpixel may display a second color, and the fifth subpixel may display a third color.

The display device may further comprise a third pixel including a sixth subpixel positioned closer to the second subpixel than the first subpixel. The grayscale of the fifth subpixel may differ from the grayscale of the sixth subpixel.

The distance difference between the second subpixel and the fifth subpixel may be equal to the distance difference between the second subpixel and the sixth subpixel.

Some of the plurality of pixels may include a first subpixel displaying a first color, a second subpixel displaying a second color, a third subpixel displaying a third color, and a fourth subpixel displaying the second color.

The grayscale displayed by each of the first subpixel and the third subpixel may be larger than the grayscale of the second subpixel and the fourth subpixel.

The display device may further comprise a second pixel including a fifth subpixel positioned closer to the second subpixel than the third subpixel of the first pixel. The third subpixel may display a first color, the fourth subpixel may display a second color, and the fifth subpixel may display a third color. The first color, the second color, and the third color may be different colors.

The display device may further comprise a third pixel including a sixth subpixel positioned closer to the second subpixel than the first subpixel. The grayscale of the fifth subpixel may differ from the grayscale of the sixth subpixel.

The distance difference between the second subpixel and the fifth subpixel may be equal to the distance difference between the second subpixel and the sixth subpixel.

Some of the plurality of pixels may include a first subpixel displaying a first color, a second subpixel displaying a second color, a third subpixel displaying a third color, and a fourth subpixel displaying the second color.

The grayscale displayed by each of the first subpixel and the third subpixel may be larger than the grayscale of the second subpixel and the fourth subpixel.

The above description has been presented to enable any person skilled in the art to make and use the technical idea of the disclosure, and has been provided in the context of a particular application and its requirements. Various modifications, additions and substitutions to the described embodiments will be readily apparent to those skilled in the art, and the general principles defined herein may be applied to other embodiments and applications without departing from the technical idea and scope of the disclosure. The above description and the accompanying drawings provide an example of the technical idea of the disclosure for illustrative purposes only. That is, the disclosed embodiments are intended to illustrate the scope of the technical idea of the disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a substrate on which a plurality of pixels including a plurality of subpixels are disposed, wherein each of the plurality of pixels includes:
a first subpixel including a first light emitting element and a first color conversion layer on the first light emitting element;
a second subpixel including a second light emitting element and a second color conversion layer on the second light emitting element;
a third subpixel including a third light emitting element and a third color conversion layer on the third light emitting element; and
a fourth subpixel including a fourth light emitting element and a fourth color conversion layer on the fourth light emitting element,
wherein the first light emitting element, the second light emitting element, and the fourth light emitting element are light emitting elements emitting light of a same color, and
wherein an insulation layer is on the first light emitting element, the second light emitting element, the third light emitting element, and the fourth light emitting element, and a black matrix is on the insulation layer.

2. The display device of claim 1, wherein light passing through the first color conversion layer and the second color conversion layer is converted into a first color.

3. The display device of claim 2, wherein light passing through the third color conversion layer is converted into a second color,
wherein light passing through the fourth color conversion layer is converted into a third color, and
wherein the first color, the second color, and the third color are different colors.

4. The display device of claim 1, wherein the first color conversion layer includes a first color conversion material layer and a first color filter, and
wherein the second color conversion layer includes a second color conversion material layer and a second color filter.

5. The display device of claim 4, wherein the first color conversion material layer includes a material included in the second color conversion material layer, and
wherein a color of light passing through the first color filter is the same as a color of light passing through the second color filter.

6. The display device of claim 4, wherein the black matrix covers the first color filter, and
wherein the black matrix does not contact an upper surface of the second color filter.

7. The display device of claim 4, wherein the third color conversion layer includes a third color conversion material layer and a third color filter,
wherein the first color conversion material layer includes a material converting a color of light, and
wherein the third color conversion material layer includes a transparent material.

8. The display device of claim 1, further comprising a first subpixel circuit driving the first light emitting element,
wherein the first subpixel circuit does not supply a data voltage to the first light emitting element or supplies a voltage for the first light emitting element to represent black.

9. The display device of claim 1, further comprising:
a first pixel including the first subpixel, the second subpixel, the third subpixel, and the fourth subpixel;
a second pixel including a fifth subpixel and the second pixel disposed in line with the first pixel; and
a third pixel including a sixth subpixel and the third pixel disposed in line with the first pixel and the second pixel, and
wherein a first distance from the second subpixel to the fifth subpixel is shorter than a second distance from the second subpixel to the sixth subpixel.

10. The display device of claim 9, wherein when the first pixel, the second pixel, and the third pixel are controlled to represent the same color, a grayscale of the fifth subpixel of the second pixel is different from a grayscale of the sixth subpixel of the third pixel.

11. The display device of claim 10, wherein the difference in grayscale between the fifth subpixel and the sixth subpixel is based on a distance from the second subpixel.

12. The display device of claim 9, wherein each of the second subpixel, the fifth subpixel, and the sixth subpixel displays a different grayscale, and
wherein the second subpixel, the fifth subpixel, and the sixth subpixel display the same color.

13. The display device of claim 9, wherein the second pixel includes a seventh subpixel disposed farther from the second subpixel than the fifth subpixel,
wherein the third pixel includes an eighth subpixel disposed closer to the second subpixel than the sixth subpixel, and
wherein a third distance from the second subpixel to the seventh subpixel is the same as a fourth distance from the second subpixel to the eighth subpixel.

14. The display device of claim 13, wherein the second subpixel displays a first color, and the seventh subpixel and the eighth subpixel display a second color different from the first color.

15. The display device of claim 1, wherein the second light emitting element does not emit light or emits light of a low grayscale, and
wherein the black matrix is disposed to overlap the second light emitting element and the second color conversion layer, and the black matrix is disposed to cover the second color conversion layer.

16. The display device of claim 15, further comprising a fifth subpixel of a second pixel closest to the second subpixel of a first pixel,
wherein the third subpixel displays a first color,
wherein the fourth subpixel displays a second color, and
wherein the fifth subpixel displays a third color, and
wherein the first color, the second color, and the third color are different colors.

17. The display device of claim 1, further comprising:
a first pixel including the first subpixel to fourth subpixel; and
a second pixel including a fifth subpixel, a sixth subpixel, a seventh subpixel, and an eighth subpixel, and
wherein the fifth subpixel has a grayscale lower than the first subpixel.

18. The display device of claim 17, wherein the black matrix is disposed on a light emitting element included in the fifth subpixel.

19. The display device of claim 17, wherein each of the plurality of pixels includes a plurality of arrangement areas, a subpixel is disposed in the arrangement area, and
wherein an arrangement area where the first subpixel is positioned in the first pixel is the same as an arrangement area where the fifth subpixel is positioned in the second pixel.

20. The display device of claim 19, wherein light displayed by the first subpixel of the first pixel and light displayed by the fifth subpixel of the second pixel are different from each other.

21. The display device of claim 1, wherein each of the plurality of pixels includes an opening area defined by an aperture through which light is emitted, and
wherein an opening area of the second subpixel is larger than an opening area of the first subpixel.
